(19) United States
(12) Patent Application Publication
(10) Pub. No.: US 2011/0057222 A1
(43) Pub. Date: Mar. 10, 2011

(54) ORGANIC ELECTROLUMINESCENT ELEMENT, AND METHOD FOR PRODUCING THE SAME

(76) Inventors: Hidemasa Hosoda, Ashigarakami-gun (JP); Kiyoshi Fujimoto, Ashigarakami-gun (JP)

(21) Appl. No.: 12/877,359

(22) Filed: Sep. 8, 2010

(30) Foreign Application Priority Data
Sep. 9, 2009 (JP) 2009-208338

(51) Int. Cl. H01L 51/56; H01L 51/52

(52) U.S. Cl. 257/98; 438/29; 257/E51.018

(57) ABSTRACT

The present invention provides a method for producing an organic electroluminescent element, the method including: arranging, on a surface of a substrate having an electrostatic charge, particles provided with a surface electrostatic charge opposite to the electrostatic charge on the surface of the substrate, so that the particles are fixed on the surface of the substrate with an electrostatic force, and forming a thin film on the surface of the substrate on which the particles have been fixed.

### BACKGROUND OF THE INVENTION

1. Field of the Invention

The present invention relates to an organic electroluminescent element (hereinafter, otherwise referred to as “organic electroluminescence element” or “organic EL element”), and a method for producing the organic electroluminescent element.

2. Description of the Related Art

Organic electroluminescent elements have such a problem that most of light emitted is trapped in organic thin layers and cannot be extracted outside the elements. To solve this problem, Japanese Patent Application Laid-Open (JP-A) No. 2001-230069 proposes an organic electroluminescent element, as illustrated in FIG. 1, in which one layer or a plurality of organic thin film layers 203 is sandwiched by a pair of electrodes 201 and 204 at least one of which is a metal electrode, a hole-electron recombination light-emitting region is located 100 nm or more away from the metal electrode, and a periodic structure 202 is formed in a direction parallel to a surface of a substrate 200. According to this proposal, the provision of a periodic structure in the organic thin film layer 203 makes it possible to efficiently extract light-emitting components having a large outgoing angle outside the organic electroluminescent element.

However, this proposal has a problem that the periodic structure is produced by using a microfabrication process such as photolithography, and thus it is difficult to provide a large area to the organic electroluminescent element because of a restriction of the microfabrication process, leading to an increase of production costs.

In addition, this proposal also has a disadvantage that the method of providing holes (concave portions) in an organic thin layer using a laser etc. is likely to cause large damage to the organic thin film layer, and it may be impossible to use the resulting organic electroluminescent element.

Accordingly, a method for producing an organic electroluminescent element enabling to efficiently produce an organic electroluminescent element, which can easily form a large surface area film and which has high light extraction efficiency and high performance, at low costs and such an organic electroluminescent element have not yet been provided so far.

### BRIEF SUMMARY OF THE INVENTION

The present invention aims to provide an organic electroluminescent element having high light extraction efficiency, causing less light bleeding and enabling reduction of power consumption and a method for producing an organic electroluminescent element.

Means to solve the above problems are as follows:
<1> A method for producing an organic electroluminescent element, including:

arranging, on a surface of a substrate having an electrostatic charge, particles provided with a surface electrostatic charge opposite to the electrostatic charge on the surface of the substrate, so that the particles are fixed on the surface of the substrate with an electrostatic force, and

forming a thin film on the surface of the substrate on which the particles have been fixed.
<2> The method according to <1> above, further including: forming a surface layer on a surface of the thin film and surfaces of the particles.
<3> The method according to <1> above, wherein the surface coverage of the particles fixed on the surface of the substrate is 0.1% to 20%.
<4> The method according to <1> above, wherein when a total thickness of the thin film formed in the forming the thin film is defined as X μm, and an average particle diameter of the particles is defined as Y μm, X and Y satisfy the relationship X/Y<1.
<5> The method according to <1> above, wherein the thin film is formed by a vacuum vapor deposition method.
<6> An organic electroluminescent element including:

a substrate having an electrostatic charge on a surface thereof, and

particles provided with a surface electrostatic charge opposite to the electrostatic charge on the surface of the substrate,

wherein the organic electroluminescent element produced by a method for producing an organic electroluminescent element which includes: arranging the particles on the surface of the substrate, so that the particles are fixed on the surface of the substrate with an electrostatic force, and forming thin films on the surface of the substrate on which the particles have been fixed.
<7> A method for producing an organic electroluminescent element, including:

arranging, on a surface of a substrate having an electrostatic charge, particles provided with a surface electrostatic charge opposite to the electrostatic charge on the surface of the substrate, so that the particles are fixed on the surface of the substrate with an electrostatic force,

forming a thin film on the surface of the substrate on which the particles have been fixed, and

removing the particles from the surface of the substrate on which the thin film has been formed.
<8> The method according to <7> above, further including: forming a surface layer on surfaces of concave portions formed by removing the particles and on a surface of the thin film.
<9> The method according to <7> above, wherein the surface coverage of the particles fixed on the surface of the substrate is 0.1% to 20%.
<10> The method according to <7> above, wherein when a total thickness of the thin film formed in the forming the thin film is defined as X μm, and an average particle diameter of the particles is defined as Y μm, X and Y satisfy the relationship X/Y<1.
<11> The method according to <7> above, wherein the thin film is formed by a vacuum vapor deposition method.
<12> The method according to <7> above, wherein the particles are removed from the surface of the substrate using an adhesive tape.
<13> An organic electroluminescent element including:
a substrate having an electrostatic charge on a surface thereof, and

particles provided with a surface electrostatic charge opposite to the electrostatic charge on the surface of the substrate,

wherein the organic electroluminescent element produced by a method for producing an organic electroluminescent element which includes: arranging the particles on the surface of the substrate, so that the particles are fixed on the surface of the substrate with an electrostatic force, forming thin films on the surface of the substrate on which the particles have been fixed, and removing the particles from the surface of the substrate on which the thin films have been formed.

According to the present invention, it is possible to solve the above-mentioned conventional problems and to provide an organic electroluminescent element having high light extraction efficiency, causing less light bleeding and enabling reduction of power consumption and a method for producing an organic electroluminescent element.

### BRIEF DESCRIPTION OF THE DRAWINGS

FIG. 1 is a schematic view illustrating one example of a conventional organic electroluminescent element having a periodic structure.

FIG. 2A is a process chart illustrating one example of a method for producing an organic electroluminescent element according to a first embodiment of the present invention.

FIG. 2B is a process chart illustrating one example of a method for producing an organic electroluminescent element according to a first embodiment of the present invention.

FIG. 2C is a process chart illustrating one example of a method for producing an organic electroluminescent element according to a first embodiment of the present invention.

FIG. 3A is a process chart illustrating one example of a method for producing an organic electroluminescent element according to a second embodiment of the present invention.

FIG. 3B is a process chart illustrating one example of a method for producing an organic electroluminescent element according to a second embodiment of the present invention.

FIG. 3C is a process chart illustrating one example of a method for producing an organic electroluminescent element according to a second embodiment of the present invention.

FIG. 4A is a process chart illustrating another example of a method for producing an organic electroluminescent element according to a second embodiment of the present invention.

FIG. 4B is a process chart illustrating another example of a method for producing an organic electroluminescent element according to a second embodiment of the present invention.

FIG. 4C is a process chart illustrating another example of a method for producing an organic electroluminescent element according to a second embodiment of the present invention.

FIG. 4D is a process chart illustrating another example of a method for producing an organic electroluminescent element according to a second embodiment of the present invention.

FIG. 5 is an SEM image illustrating a state where particles are arranged on a substrate.

FIG. 6 is an SEM image illustrating a state where particles are removed from a surface of a substrate surface after formation of a thin layer on the substrate.

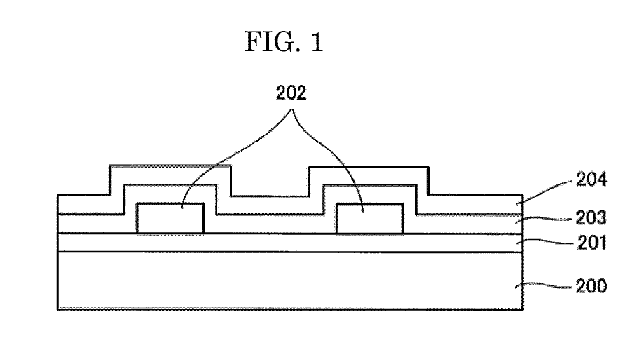

### DETAILED DESCRIPTION OF THE INVENTION

### Organic Electroluminescent Element According to a First Embodiment and Production Method of an Organic Electroluminescent Element According to a First Embodiment

A method for producing an organic electroluminescent element according to the first embodiment of the present invention includes a step of fixing particles, and a thin-film forming step, and a surface-layer forming step, and may further include other steps as required.

The organic electroluminescent element according to the first embodiment of the present invention is produced by a method for producing an organic electroluminescent element according to the first embodiment of the present invention.

Hereinafter, details of the organic electroluminescent element according to the first embodiment of the present invention will be described through the description of the method for producing an organic electroluminescent element according to the first embodiment of the present invention.

### <Particle-Fixing Step>

The step of fixing particles is a step in which on a surface of a substrate having an electrostatic charge on the surface thereof, particles provided with a surface electrostatic charge opposite to the electrostatic charge are arranged and fixed with an electrostatic force.

### —Substrate—

The substrate is not particularly limited as to the material, shape, structure, size and the like, and may be suitably selected in accordance with the intended use. Examples of the shape include a flat plate shape. The structure may be a single layer structure or a multilayer structure. The size can be suitably selected depending on the intended application.

The material of the substrate is not particularly limited and may be suitably selected in accordance with the intended use. It is, however, preferably a material capable of having an electrostatic charge on its surface. Examples thereof include glass, metal oxides (e.g., aluminum oxide, SiO, and ITO), plastic films coated with each of these metal oxides (e.g., a polyethylene terephthalate (PET) film, a polyethylene naphthalate (PEN) film, and a polycarbonate film).

In the case of the metal oxide, since a material rich in reactivity (such as aluminum) can easily form an oxide film on its surface, it can be used without modification. However, in the case of gold, platinum, etc., it is preferable to form a monolayer on its surface with a compound containing a thiol group (e.g., 11-amino-1-undecanethiol, 10-carboxy-1-decanethiol, and 11-hydroxy-1-undecanethiol). Further, the hydrophilicity, electrostatic charge and concavo-convexes of the substrate surface affects the adhesive force of the particles, and thus it is preferable to control them.

As the treatment of the substrate surface, i.e., forming a monolayer with a compound containing a thiol group, it is preferable to subject the surface of the substrate to a pre-treatment complying with an immersion adsorption method, in the light of the properties of the substrate surface. Preferred examples of the pretreatment include ozone washing using ultraviolet ray (UV), and a surface modification using a surface modifier (e.g., poly(diallyldimethyl ammonium chloride) (PDDA), poly(styrene sodium sulfonate), and poly(3,4-oxyethylene oxythiophene)).

The thickness of the substrate is not particularly limited and may be suitably selected in accordance with the intended use. For example, when a glass substrate is used, the thickness thereof is preferably 0.1 mm to 10 mm. When a film substrate is used, the thickness thereof is preferably 1 μm to 1 mm.

In addition, a thin film may be formed on the substrate before particles are arranged on the substrate, provided that formation of the thin film does not impede arrangement of particles. Such a thin film can be suitably selected from an electrode layer, a charge transport layer, a hole transport layer, a light emitting layer, a charge injection layer, and a hole injection layer, depending on the layer structure of the resulting organic electroluminescent element.

### —Particles—

The particles do not move and aggregate in the production process, because the surface of the particles is provided with a surface electrostatic charge opposite to the electrostatic charge of the charged substrate, and thus the particles are fixed on the substrate by an electrostatic force.

The particles are not particularly limited and may be suitably selected in accordance with the intended use. Examples thereof include polystyrene particles, polymethyl methacrylate particles, and benzyl polymethacrylate particles.

The electrostatic interaction between the particles and the substrate can be controlled by the shape of particles as well as the surface treatment method employed. It is more preferably to employ the shape of particles and surface treatment method suitable for removing the particles after a thin film is formed on the substrate.

The shape of the particles is not particularly limited and may be suitably selected in accordance with the intended use. Examples of the shape include a spherical shape, an oval sphere shape, and a polyhedral shape. Among these shapes, a sphere shape is particularly preferable.

As the surface modification of the particles, preferred are core-shell formation of the particles, chemical modification of particles, plasma treatment, addition of a surfactant to the particles, and addition of a substituent (e.g., a carboxyl group, a trialkyl ammonium group, an amino group, a hydroxyl group, and a sulfonic acid group) to the particles.

The average particle diameter of the particles is preferably from 1 nm to 10 μm, more preferably from 10 nm to 10 μm, and particularly preferably 30 nm to 1 μm. When the average particle diameter is greater than 10 μm, it may be difficult to control the arrangement and fixing the particles on the substrate by only an electrostatic force due to influence of the mass of the particles.

The average particle diameter of the particles can be measured by observing an SEM image obtained by a scanning electron microscope (SEM).

The particles are preferably mono-dispersed particles, and a coefficient of variation of the particles is preferably 50% or lower, more preferably 20% or lower, and particularly preferably 10% or lower. Here, the term of “a coefficient of variation” indicates a percentage of a standard deviation of particle diameters of individual particles relative to the average particle diameter thereof, and otherwise referred to as “CV value”.

As the surface treatment of particles, for example, according to the method described in Japanese Patent Application Laid-Open (JP-A) No. 2007-184278, it is preferable that after particles are coated with a reflective layer made of Ag or the like, and then an insulation layer is formed on the particles by a solution method, oxidization by a vapor phase reaction or vapor deposition, followed by subjecting them to the surface treatment.

As the density of the particles on the substrate, a surface coverage of the particles when arranged in a monolayer on the substrate and viewed from a perpendicular to the plane of the substrate is preferably 0.1% to 20%, and more preferably 0.1% to 15%. When the surface coverage of the particles is less than 0.1%, improvement in light extraction efficiency may be hardly obtained. When the surface coverage is more than 20%, a desired light-emission luminance may not be obtained due to a reduction of light emission area.

Here, the surface coverage of the particles can be determined as follows. First, a surface coverage or an open area ratio of particles is obtained by observing an SEM image obtained by a scanning electron microscope (SEM), and the obtained value is converted to a value per unit area of each particle.

The method of arranging the particles on the substrate is not particularly limited and may be suitably selected in accordance with the intended use. Examples thereof include a bar coating method, squeegee coating method, spin-coating method, ink jet method, and spray method. Among these methods, a spin-coating method is preferable in that the particles can be arranged uniformly in a relatively small area on the substrate, and a spray method is preferable in that particles can be arranged uniformly in a relatively large area on the substrate.

In this case, to make the resulting organic electroluminescent element reach stable performance, a method of arranging particles more uniformly is necessary. In the present invention, it is preferable to arrange and fix particles on a substrate by an immersion adsorption method through use of the method of fabricating a switching element described in JP-A No. 2007-87974.

In the arrangement of particles on the substrate, it is preferable to sufficiently increase the interaction between the substrate and the particles. If the substrate itself has a sufficient electrostatic charge, the particles can be directly arranged and fixed on the substrate.

In contrast, if the substrate itself does not have an electrostatic charge or even if the substrate has an electrostatic charge but the electrostatic charge is weak, a surface modifier is used. The electrostatic charge can be increased by modifying the substrate surface. Also, when the substrate and the particles have the same electrostatic charge, a surface modifier is preferably used. The substrate surface is made to have an opposite charge to that of the particles, and thereby the arrangement of the particles can be achieved. Further, it is also possible to form a laminated surface modifier layer on the substrate by using a plurality of surface modifiers, if necessary.

First, since a substrate (with particles being arranged on its surface) taken out from a dispersion liquid has a remaining dispersion medium, the substrate is preferably dried by air seasoning at room temperature, air drying with an compressed air, drying under reduced pressure, or increasing the temperature thereof. When the substrate is taken out from a dispersion liquid and dried, particles arranged on the substrate unfavorably have a property to aggregate, and it is necessary to take a measure to prevent this. If the particles aggregate, uniform dispersibility of the arranged particles is impaired, possibly causing a reduction of performance of the resulting organic electroluminescent element. Such aggregation occurs, since when a dispersion medium remaining on the substrate is dried, a microscopic meniscus is formed between particles, and a capillary force works between the particles. To control the aggregation, it is preferable that an electrostatic interaction between the substrate and the particles be increased to thereby increase the fixing strength of the particles to the substrate.

To increase the fixing strength therebetween, it is preferable that particles are moderately softened by heating to increase the contact area between the particles and the substrate. The heating method is not particularly limited, as long as the heating does not deteriorate the substrate and can moderately soften the arranged particles, and may be suitably selected in accordance with the intended use. Examples of the heating method include a method of rinsing particles in a liquid; a method of dipping the substrate in a heated particle-dispersion liquid; and a method of directly heating the substrate by a hot plate, or the like.

In the case of the heating method of rinsing particles in a liquid, as a rinsing medium, an aqueous medium (e.g., distilled water, ultra pure water, and ion exchanged water); an organic solvent (e.g., alcohol, and acetone), or a mixture liquid thereof is preferably used. From the viewpoint of the handling ability and industrial capability, an aqueous medium is more preferable. The heating time can be suitably determined. It is, however, preferably from 1 second to 10 minutes, and more preferably 10 seconds to 1 minute. The heating temperature is preferably a temperature at which particles are moderately softened so as to be fixed on the substrate. The heating temperature can be suitably determined depending on the particles used. For example, when a polymer particle is used, it is preferable that the particles be heated and softened at a temperature near the glass transition temperature (Tg) of the polymer. Specifically, the heating temperature is preferably from a temperature that is at or lower than 30° C. higher than the glass transition temperature to a temperature that is at or higher than 30° C. lower than the glass transition temperature; and more preferably from a temperature that is at or lower than 10° C. higher than the glass transition temperature to a temperature that is at or higher than 10° C. lower than the glass transition temperature. More specifically, in the light of the heating the particles in a rinsing liquid using an aqueous solvent and the production of an organic electroluminescent element, the heating temperature is preferably from 70° C. to 100° C., and more preferably from 80° C. to 100° C.

Next, after the heating, in order to surely prevent aggregation of particles, it is preferable to cool the particles. For example, the particles are preferably rinsed with cooling water (e.g., water at room temperature or lower). In addition, it is preferable to wash out any excess particles on the substrate after particles are adsorbed on the substrate. If this washing treatment is not performed, the particles are not formed into a mono-particle layer, resulting in the occurrence of a region where the particles are piled up. The timing of performing the processes of drying, heating, cooling and washing can be suitably determined in consideration of the working efficiency. It is, however, preferable that after arrangement of particles, the particles be subjected to these processes, and then a thin layer be formed on the substrate. When particles are subjected to heating and cooling treatments in a rinsing liquid, the heating and cooling treatments also serve as the washing treatment.

The solvent for use in the dispersion liquid is not particularly limited, as long at it does not hinder an electrostatic interaction between the particles and the substrate and can stably disperse particles during the treatment process, and may be suitably selected in accordance with the intended use. Water or an organic solvent may be used as the solvent, however, from the viewpoint of ease of preparation of a dispersion liquid and making the electrostatic interaction strongly, water is preferably used.

To improve the dispersibility of the particles, a surfactant may be added to the dispersion liquid. The dispersion concentration of the particles can be suitably controlled depending on the characteristic of the particles or the substrate and the density of the particles arranged. The dispersion concentration is preferably 0.01% by mass to 10% by mass, and more preferably 0.1% by mass to 1% by mass.

### <Thin-Film Forming Step>

The thin-film forming step is a step of forming a thin film on a surface of the substrate on which the particles are fixed.

The method of forming a thin film is not particularly limited and may be suitably selected in accordance with the intended use. Examples thereof include various thin-film forming methods such as a sputtering method, vapor deposition method, thin-film patterning method (e.g., coating method), and spray method. Among these methods, a vapor deposition method is particularly preferable.

When n the thin-film forming step, a thin film is formed by a vapor deposition method and if the particle size is greater than the film thickness of the thin film, a thin film is formed in a state where the film formed on surfaces of particles and the film formed on the substrate surface are in electrically noncontact with each other.

The thin film may be a single-layer film or may be a laminated thin film.

When the thin film is a laminated thin film, the number of stacked films is not particularly limited and may be suitably selected in accordance with the intended use.

Each layer formed in a laminated thin film corresponds to each functional layer of a resulting organic electroluminescent element. Examples of the layers formed in the multi-layer include a reflective electrode layer, organic thin-film layers (an electron injection layer, an electron transport layer, a light emitting layer, a hole transport layer, and a hole injection layer), and a semi-transmissive electrode layer.

The total thickness of these thin films can be determined for each material used, from the viewpoint of the designed operation of the resulting organic electroluminescent element, depending on the sensitivity for mechanically and selectively separating films from the substrate, and on a thickness ratio selected. The total thickness is preferably 1 nm to 10 μm, and more preferably 50 nm to 1,000 nm.

The thickness of the thin film can be measured, for example, by observing a cross-sectional TEM image of the films.

When a total thickness of the thin film(s) formed in the thin-film forming step is defined as X μm, and an average particle diameter of the particles is defined as Y μm, X and Y preferably satisfy the relationship X/Y<1, and more preferably satisfy the relationship X/Y≦½. When the value of X/Y is 1 or more, the film formed on surfaces of particles and the film formed on the substrate surface are electrically brought into contact in the formation of the film, possibly leading to a performance degradation of the element.

### <Surface Layer Forming Step>

The surface layer forming step is a step of forming a surface layer on the thin-film surface and the surfaces of the particles.

The surface layer is not particularly limited and may be suitably selected in accordance with the intended use. Examples thereof include an insulation layer, and a reflective layer.

The material for the insulation layer is not particularly limited and may be suitably selected in accordance with the intended use. Examples thereof include SiONx, SiO₂, SiNx, ZnO, ZnS, ZnSe, TiO₂, and ZrOx.

The material for the reflective layer is not particularly limited and may be suitably selected in accordance with the intended use. Examples thereof include aluminum (Al), Ag, and Mg.

The surface layer can be formed by various thin-film forming methods such as a sputtering method, vapor deposition method, thin-film patterning method (e.g., coating method), and spray method. In the present invention, the surface layer forming method can be suitably selected from these methods according to the material used.

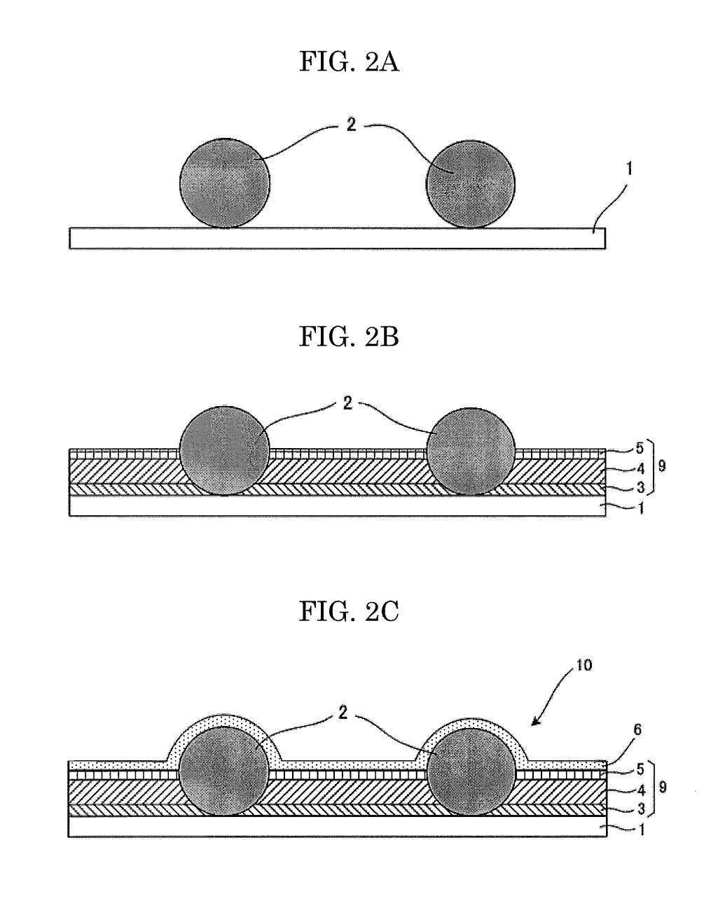

Here, FIGS. 2A to 2C each are process charts illustrating one example of a method for producing an organic electroluminescent element according to a first embodiment of the present invention.

As illustrated in FIG. 2A, on a substrate 1 having an electrostatic charge on a surface thereof, particles 2 provided with a surface electrostatic charge opposite to the electrostatic charge on the surface of the substrate 1 are arranged and fixed with an electrostatic force.

Next, as illustrated in FIG. 2B, on the substrate 1 with the particles 2 being fixed on the surface thereof, a reflective electrode layer 3, an organic thin-film layer 4 and a semi-transmissive electrode layer 5 are formed by a vacuum deposition method.

Further, as illustrated in FIG. 2C, a sealing layer 6 can also be formed as a surface layer on the laminated thin film surface and the surfaces of the particles 2.

With the above described procedure, an organic electroluminescent element 10 according to the first embodiment of the present invention is produced.

FIG. 2C illustrates one example of an organic electroluminescent element according to the first embodiment produced by the method for producing an organic electroluminescent element according to the first embodiment of the present invention.

In an organic electroluminescent element 10 illustrated in FIG. 2C, particles 2 are fixed on the substrate 1 and a laminated thin film 9 constituted by a reflective electrode layer 3, an organic thin-film layer 4, and a semi-transmissive electrode layer 5 is formed over the substrate 1. On the surface of the laminated thin film 9 and the surfaces of particles 2, a sealing layer 6 is formed as a surface layer, and the particles 2 are exposed by about half of the laminated thin film 9. The surface of this organic electroluminescent element 10 with the particles 2 being fixed functions as a light extracting surface, and the organic electroluminescent element 10 is suitably used as a top-emission type electroluminescent element.

### Organic Electroluminescent Element According to Second Embodiment and Method for Producing an Organic Electroluminescent Element According to Second Embodiment

A method for producing an organic electroluminescent element according to a second embodiment of the present invention includes a particle-fixing step, a thin-film forming step and a particle-removing step, includes a post-particle removing-surface layer forming step (a surface layer forming step after removal of particles), and may further include other steps as required.

An organic electroluminescent element according to the second embodiment is produced by the method for producing an organic electroluminescent element according to the second embodiment.

Hereinafter, details of the organic electroluminescent element according to the second embodiment of the present invention will be described through the description of the method for producing an organic electroluminescent element according to the second embodiment of the present invention.

### <Particle-Fixing Step>

The particle-fixing step is the same as the particle-arranging step in the method for producing an organic electroluminescent element according to the first embodiment of the present invention.

### <Thin Film Forming Step>

The thin-film forming step is the same as the thin film forming step in the method for producing an organic electroluminescent element according to the first embodiment of the present invention.

### <Post-Particle Removing-Surface Layer Forming Step>

The post-particle removing-surface layer forming step is the same as the surface layer forming step in the method for producing an organic electroluminescent element according to the first embodiment of the present invention, except that this step is performed after removing the particles.

### <Particle-Removing Step>

The particle-removing step is a step of removing the particles after forming the thin film layer.

The method of removing the particles is not particularly limited, as long as it is a method capable of surely removing the particles without damaging the thin film formed, and may be suitably selected in accordance with the intended use. Examples thereof include a method of removing particles using an adhesive sheet; and a method of removing particles by subjecting particles to an ultrasonic wave treatment in a liquid. Among these methods, the method of removing particles using an adhesive sheet is particularly preferable.

The particle removing method using an adhesive sheet is suitably used because the method can also be used for a material that cannot be treated with solvents. In the particle removing method using an adhesive sheet, particles can be peeled off from the substrate by using an adhesive sheet having a higher adhesion force between particles and the sheet itself than the adhesion force between particles and the substrate. However, when the adhesion force of the adhesive sheet is excessively high, it may damage the multilayer thin film, and thus it is preferable to use an adhesive sheet having an appropriate adhesion force.

As a solvent for use in the method of removing particles by subjecting particles to an ultrasonic wave treatment in a liquid, it is preferable to select a solvent capable of dispersing particles and causing no damage to the thin film. For example, if the thin film to be formed is made of a material hardly soluble in an organic solvent and the particles are hydrophilic, it is preferable to use a hydrophilic organic solvent.

In order to increase the peelability and selectivity of solvents, it is preferable to select the temperature of a washing liquid, the intensity of an ultrasonic wave and the frequency as required.

The frequency of the ultrasonic wave is preferably 100 Hz to 100 MHz, and more preferably 1 kHz to 10 MHz. It is more preferable to irradiate particles with an ultrasonic wave having a wide range of different frequencies at a time, and also preferable to switch the frequency of an ultrasonic wave to another frequency to thereby irradiate particles.

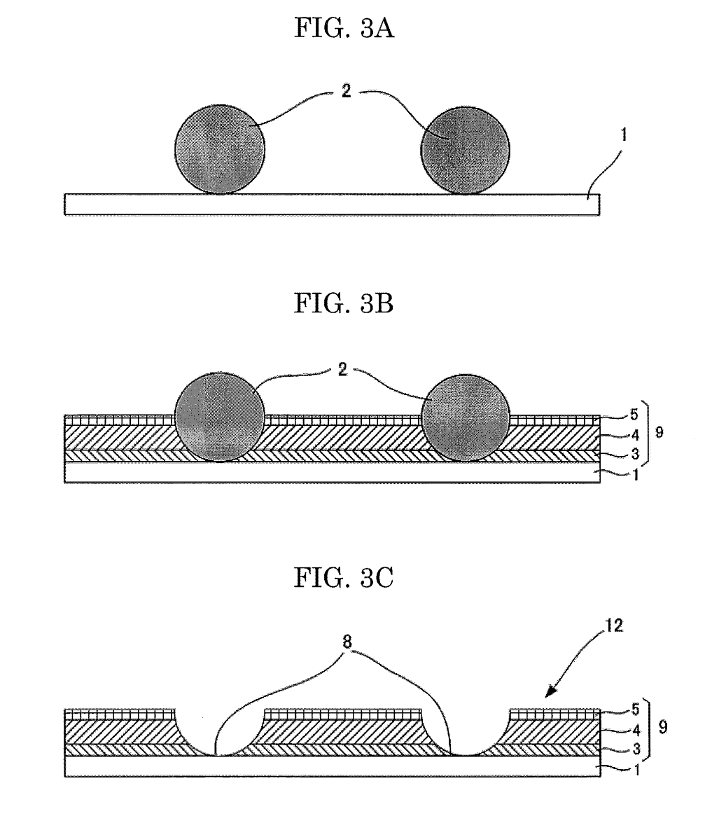

Here, in FIGS. 3A to 3C each are process charts illustrating one example of a method for producing an organic electroluminescent element according to a second embodiment of the present invention.

As illustrated in FIG. 3A, on a substrate 1 having an electrostatic charge on a surface thereof, particles 2 provided with a surface electrostatic charge opposite to the electrostatic charge on the surface of the substrate 1 are arranged and fixed with an electrostatic force.

Next, as illustrated in FIG. 3B, on the substrate 1 with the particles 2 being fixed on the surface thereof, a laminated thin film 9 constituted by a reflective electrode layer 3, an organic thin-film layer 4 and a semi-transmissive electrode layer 5 is formed by a vacuum deposition method.

Next, as illustrated in FIG. 3C, the particles 2 are removed from the laminated thin film 9 using, for example, an adhesive tape.

With the above described procedure, an organic electroluminescent element 12 according to the second embodiment of the present invention is produced.

FIG. 3C illustrates one example of an organic electroluminescent element according to the second embodiment produced by the method for producing an organic electroluminescent element according to the second embodiment of the present invention.

In an organic electroluminescent element 12 illustrated in FIG. 3C, a laminated thin film 9 constituted by a reflective electrode layer 3, an organic thin-film layer 4 and a semi-transmissive electrode layer 5 is formed over the substrate 1, and concave portions 8, which are formed after the particles 2 are removed from the laminated thin film 9 are formed. On the surface of the laminated thin film 9 and the surfaces of particles 2, a sealing layer 6 is formed as a surface layer, and the particles 2 are exposed by about half of the laminated thin film 9. The surface of the organic electroluminescent element 12 provided with the concave portions 8 functions as a light extracting surface, and the organic electroluminescent element 12 is suitably used as a top-emission type electroluminescent element.

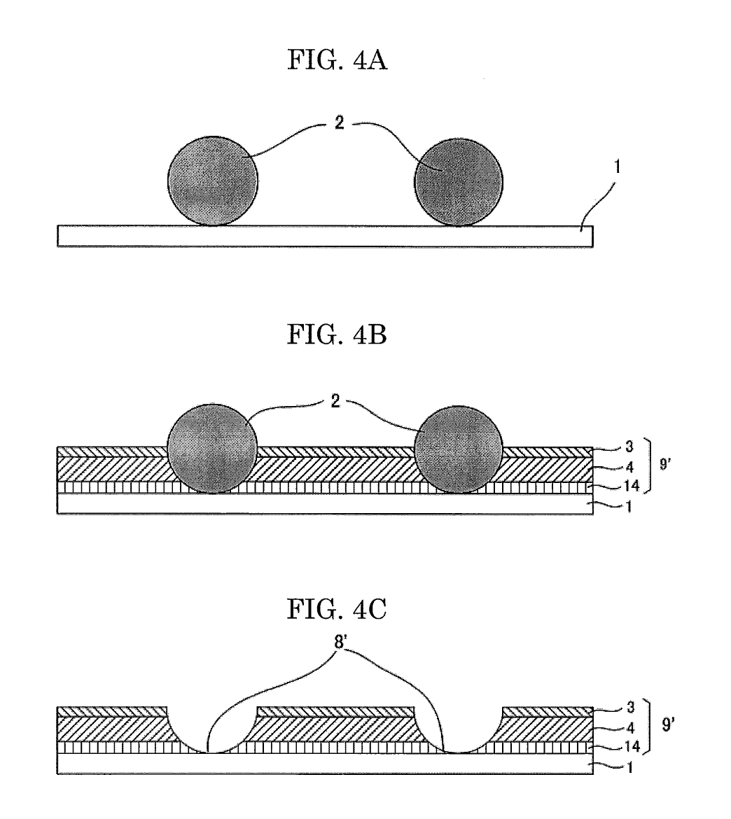

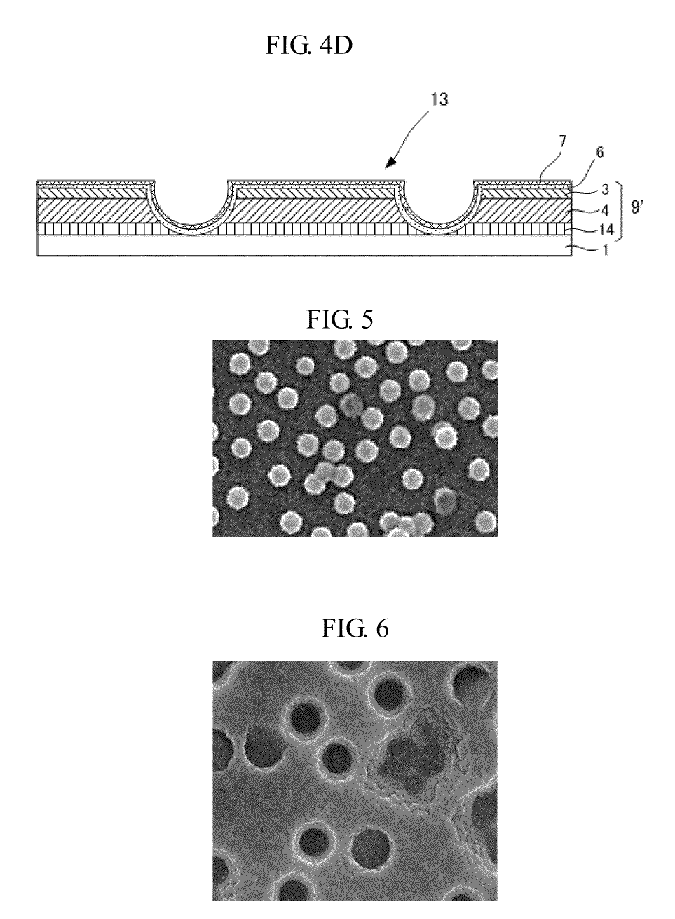

Next, FIGS. 4A to 4D each are process charts illustrating another example of a method for producing an organic electroluminescent element according to the second embodiment of the present invention.

As illustrated in FIG. 4A, on a substrate 1 having an electrostatic charge on a surface thereof, particles 2 provided with a surface electrostatic charge opposite to the electrostatic charge on the surface of the substrate 1 are arranged and fixed with an electrostatic force.

Next, as illustrated in FIG. 4B, on the substrate 1 with the particles 2 being fixed on the surface thereof, a laminated thin film 9′ constituted by a transparent electrode layer 14, an organic thin-film layer 4 and a reflective electrode layer 3 is formed by a vacuum deposition method.

Next, as illustrated in FIG. 4C, the particles 2 are removed from the laminated thin film 9′ using, for example, an adhesive tape.

Further, as illustrated in FIG. 4D, over the surface of the laminated thin film 9′ and surfaces of concave portions 8′, an insulation layer 6 and a reflective layer 7 are formed as surface layers.

With the above described procedure, an organic electroluminescent element 13 according to the second embodiment of the present invention is produced.

FIG. 4D illustrates another example of an organic electroluminescent element according to the second embodiment produced by the method for producing an organic electroluminescent element according to the second embodiment of the present invention.

In an organic electroluminescent element 13 illustrated in FIG. 4D, a laminated thin film 9′ constituted by a transparent electrode layer 14, an organic thin-film layer 4 and a reflective electrode layer 3 is formed over the substrate 1, and concave portions 8′, which are formed after the particles 2 are removed from the laminated thin film 9′, are formed. On the surface of the laminated thin film 9′ and the surfaces of particles 2, an insulation layer 6 and a reflective layer 7 are formed. The surface of the organic electroluminescent element 13 provided with no surface layer functions as a light extracting surface, and the organic electroluminescent element 13 is suitably used as a bottom-emission type electroluminescent element.

### <Organic Electroluminescent Element>

An organic electroluminescent element of the present invention has at least a light emitting layer between an anode and a cathode and may have a hole injection layer, a hole transport layer, an electron injection layer, an electron transport layer, and a substrate as necessary. These layers may each have different functions. To form these layers, various different materials may be used for each layer.

### —Anode—

The anode supplies holes to a hole injection layer, a hole transport layer, a light emitting layer, etc. As a material of the anode, metals, alloys, metal oxides, electrically conductive compounds and a mixture of these materials can be used. Preferred is a material having a work function of 4 eV or more. Specific examples of the material include conductive metal oxides (e.g., tin oxides, zinc oxides, indium oxides, and indium tin oxides (ITO)); metals (e.g., gold, silver, chromium, and nickel) or mixtures or laminates of these metals with the conductive metal oxides; inorganic conductive materials (e.g., copper iodide, and copper sulfide); organic conductive materials (e.g., polyaniline, polythiophene, and polypyrrole) or laminates of these organic conductive materials with ITO. Among these materials, conductive metal oxides are preferable, and ITO is particularly preferably in terms of the productivity, high-conductivity, transparency and the like.

The thickness of the anode is not particularly limited and may be suitably adjusted depending on the material used, however, it is preferably 10 nm to 5 μm, more preferably 50 nm to 1 μm, and still more preferably 100 nm to 500 nm.

As the anode, generally, the one that is produced by forming layers on a soda lime glass, alkali-free glass, a transparent resin substrate or the like is used. When glass is used, for the reason of characteristics of glass, it is preferable to use alkali-free glass to suppress eluted ions. When soda lime glass is used, it is preferable to use the one provided with a barrier coat such as a silica.

The thickness of the substrate is not particularly limited, as long as the substrate has a thickness enough to maintain the mechanical strength. When glass is used for the substrate, the thickness is preferably 0.2 mm or more, and more preferably 0.7 mm or more.

As the transparent resin substrate, a barrier film can also be used. The barrier film is a film in which a gas-impermeable barrier layer is provided on a plastic substrate. Examples of the barrier film include barrier films produced by vapor deposition of a silicon oxide or aluminum oxide (Japanese Patent Application Publication (JP-B) No. 53-12953, Japanese Patent Application Laid-Open (JP-A) No. 58-217344); barrier films having an organic/inorganic composite material hybridized coating layer (JP-A Nos. 2000-323273, and 2004-25732); a barrier film containing an inorganic laminar compound (JP-A No. 2001-205743); barrier films produced by laminating inorganic materials (JP-A Nos. 2003-206361, and 2006-263989); barrier films in which an organic layer and an inorganic layer are alternately laminated (JP-A No. 2007-30387, U.S. Pat. No. 6,413,645; Thin Solid Films, pp. 290-291 (1996), by Affinito et.al.), and a barrier film in which an organic layer and an inorganic layer are continuously laminated (U.S. Patent Serial No. 2004-46497).

In the production of the anode, various methods are employed according to the material used. For example, in the case of ITO, examples of the film formation method include an electron beam method, a sputtering method, a resistance heating vapor deposition method, a chemical reaction method (e.g., sol-gel method), and a method of coating an indium tin oxide dispersion. When the anode is subjected to cleaning or other treatments, this enables decreasing the driving voltage or improving the light emission efficiency of the display device. For example, in the case of ITO, a UV-ozone treatment or the like is effective.

### —Cathode—

The cathode supplies electrons to an electron injection layer, an electron transport layer, a light emitting layer or the like, and the material therefor is selected by taking into consideration of the adhesion to a layer adjacent to the negative electrode (such as an electron injection layer, and electron transport layer, light-emitting layer), the ionization potential, the stability and the like.

As a material of the cathode, a metal, an alloy, a metal oxide, an electrically conductive compound or a mixture thereof can be used. Specific examples of the material include an alkali metal (e.g., Li, Na, K) or a fluoride thereof; an alkaline earth metal (e.g., Mg, Ca) or a fluoride thereof; gold, silver, lead, aluminum, an alloy or mixed metal of sodium and potassium, an alloy or mixed metal of lithium and aluminum, an alloy or mixed metal of magnesium and silver, and a rare earth metal such as indium and ytterbium. Among these, preferred is a material having a work function of 4 eV or less, and more preferred are aluminum, an alloy or mixed metal of lithium and aluminum, and an alloy or mixed metal of magnesium and silver.

The thickness of the cathode is not particularly limited and may be suitably selected depending on the material used. The thickness is, however, preferably from 10 nm to 5 μm, more preferably from 50 nm to 1 μm, still more preferably from 100 nm to 1 μm.

In the production of the cathode, for example, an electron beam method, a sputtering method, a resistance heating vapor deposition method and a coating method are used, and a single metal component may be vapor-deposited or two or more components may be simultaneously vapor-deposited. Furthermore, an alloy electrode may also be formed by simultaneously vapor-depositing a plurality of metals, or an alloy previously prepared may be vapor-deposited.

The sheet resistance of the anode and cathode is preferably lower, and is preferably several hundreds of Ω/square or less.

### —Light Emitting Layer—

The material of the light emitting layer is not particularly limited and may be selected in accordance with the intended use. For example, it is possible to use materials capable of forming a layer having functions to receive, at the time of electric field application, holes from the anode, hole injection layer or hole transport layer, and to receive electrons from the cathode, electron injection layer or electron transport layer, a function to move a received charge and a function to offer the field of recombination of holes and electrons to emit light.

The material of the light emitting layer is not particularly limited and may be suitably selected in accordance with the intended use. Examples thereof include various metal complexes as typified by a metal complex or rare earth complex of benzoxazole derivatives, benzimidazole derivatives, benzothiazole derivatives, styrylbenzene derivatives, polyphenyl derivatives, diphenylbutadiene derivatives, tetraphenylbutadiene derivatives, naphthalimide derivatives, coumarin derivatives, perylene derivatives, perynone derivatives, oxadiazole derivatives, aldazine derivatives, pyralidine derivatives, cyclopentadiene derivatives, bisstyrylanthracene derivatives, quinacridone derivatives, pyrrolopyridine derivatives, thiadiazolopyridine derivatives, cyclopentadiene derivatives, styrylamine derivatives, aromatic dimethylidine compound or 8-quinolinol derivatives; and a polymer compound such as polythiophene, polyphenylene and polyphenylene-vinylene. These materials may be used alone or in combination.

The thickness of the light emitting layer is not particularly limited and may be suitably selected in accordance with the intended use. The thickness is, however, preferably from 1 nm to 5 μm, more preferably from 5 nm to 1 μm, still more preferably from 10 nm to 500 nm.

The method of forming the light emitting layer is not particularly limited, and may be suitably selected in accordance with the intended use. Examples of the method include a resistance heating vapor deposition method, an electron beam method, a sputtering method, a molecular lamination method, a coating method (e.g., spin coating, casting, and dip coating) and a LB method. Among these, resistance heating vapor deposition method and coating method are preferable.

### —Hole Injection Layer, Hole Transport Layer—

The material of the hole injection layer and hole transport layer is not particularly limited, as long as it has any one of a function of receiving holes from the anode, a function of transporting holes, and a function of blocking the electrons injected from the cathode, and may be suitably selected in accordance with the intended use.

Examples thereof include a carbazole derivative, triazole derivative, oxazole derivative, oxadiazole derivative, imidazole derivative, polyarylalkane derivative, pyrazoline derivative, pyrazolone derivative, phenylenediamine derivative, arylamine derivative, amino-substituted chalcone derivative, styrylanthracene derivative, fluorenone derivative, hydrazone derivative, stilbene derivative, silazane derivative, aromatic tertiary amine compound, styrylamine compound, aromatic dimethylidine compound, porphyrin-based compound, polysilane-based compound, poly(N-vinylcarbazole) derivative, aniline-based copolymer, and an electrically conductive polymer or oligomer such as thiophene oligomer and polythiophene. These materials may be used alone or in combination.

The hole injection layer and hole transport layer may take a single-layer structure containing one or two or more of the above-mentioned materials, or a multilayer structure composed of plural layers of a homogeneous composition or a heterogeneous composition.

As the method of forming the hole injection layer and hole transport layer, a vacuum vapor deposition method, a LB method, or a method of dissolving or dispersing the above-described hole injection/transport material in a solvent and coating the obtained solution (e.g., spin coating, casting, dip coating) is used. In the case of a coating method, the above-described hole injection/transport material can be dissolved or dispersed together with resin components in the solvent.

The resin component is not particularly limited and may be suitably selected in accordance with the intended use. Examples of the resin component include polyvinyl chloride, polycarbonate, polystyrene, polymethyl methacrylate, polybutyl methacrylate, polyester resin, polysulfone resin, polyphenylene oxide resin, polybutadiene, poly(N-vinylcarbazole) resin, hydrocarbon resin, ketone resin, phenoxy resin, polyamide resin, ethyl cellulose, vinyl acetate resin, ABS resin, polyurethane resin, melamine resin, unsaturated polyester resin, alkyd resin, epoxy resin and silicone resin. These may be used alone or in combination.

The thickness of the hole injection layer and hole transport layer is not particularly limited and may be suitably selected in accordance with the intended use. The thickness is, for example, preferably 1 nm to 5 μm, more preferably 5 nm to 1 μm, and still more preferably 10 nm to 500 nm.

### —Electron Injection Layer and Electron Transport Layer—

The material of the electron injection layer and electron transport layer is not particularly limited, as long as it has any one of a function of receiving electrons from the cathode, a function of transporting electrons, and a function of blocking the holes injected from the anode, and may be suitably selected in accordance with the intended use.

Examples of the material of the electron injection layer and electron transport layer include various metal complexes as typified by a metal complex of triazole derivatives, oxazole derivatives, oxadiazole derivatives, fluorenone derivatives, anthraquinodimethane derivatives, anthrone derivatives, diphenylquinone derivatives, thiopyran dioxide derivatives, carbodiimide derivatives, fluorenylidenemethane derivatives, distyrylpyrazine derivatives, heterocyclic tetracarboxylic acid anhydride (e.g., naphthaleneperylene), phthalocyanine derivatives or 8-quinolinol derivatives, and a metal complex in which the ligand is metal phthalocyanine, benzoxazole or benzothiazole. These may be used alone or in combination.

The electron injection layer and electron transport layer may take a single-layer structure containing one or two or more of the above-mentioned materials, or a multilayer structure composed of plural layers of a homogeneous composition or a heterogeneous composition.

As the method of forming the electron injection layer and electron transport layer, a vacuum vapor deposition method, a LB method, or a method of dissolving or dispersing the above-described electron injection/transport material in a solvent and coating the obtained solution (e.g., spin coating, casting, dip coating) is used. In the case of a coating method, the above-described electron injection/transport material can be dissolved or dispersed together with resin components in the solvent. As the resin component, for example, the resin components exemplified as described above for the hole injection and transport layers can be used.

The thickness of the electron injection layer and electron transport layer is not particularly limited, and may be suitably selected in accordance with the intended use. The thickness is, however, preferably from 1 nm to 5 μm, more preferably from 5 nm to 1 μm, and still more preferably from 10 nm to 500 nm.

### —Other Structures—

The other structures are not particularly limited and may be suitably selected in accordance with the intended use. Examples thereof include a protective layer, a sealing cell, a resin-sealing layer, and a sealing adhesive.

Details of the protective layer, sealing cell, resin-sealing layer and sealing adhesive are not particularly limited and may be suitably selected in accordance with the intended use. For example, those described in JP-A No. 2009-152572 can be used.

### —Driving—

Light emission of the organic electroluminescent element of the present invention can be obtained by applying a DC (if necessary, AC component may be contained) voltage (generally from 2 volts to 15 volts) between the anode and the cathode, or by applying a DC electric current therebetween.

The organic electroluminescent element of the present invention can be used together with a thin film transistor (TFT) in an active matrix display device. As an active layer of a thin film transistor, amorphous silicon, high-temperature polysilicon, low-temperature polysilicon, micro-crystal silicon, oxide semiconductor, organic semiconductor, carbon nano-tube, and the like can be used.

To the organic electroluminescent element of the present invention, the thin film transistors disclosed, for example, in International Publication No. WO/2005/088726, JP-A No. 2006-165529, U.S. Patent Application Serial No. 2008/0237598 and the like can be applied.

The organic electroluminescent element of the present invention can be improved in its light extraction efficiency by using various conventionally known devices, without particular limitation. For example, the light exaction efficiency and external quantum efficiency thereof can be improve by processing the surface shape of a substrate (for example, a fine concave-convex pattern is formed), by controlling refractive indices of a substrate, an ITO layer and an organic layer, by controlling the thicknesses of a substrate, an ITO layer and an organic layer, or the like.

The light extracting structure for extracting light from the organic electroluminescent element of the present invention may be a top emission type and may be a bottom emission type.

The organic electroluminescent element of the present invention may have a resonance structure. For example, a first aspect of the organic electroluminescent element has, over a transparent substrate, a multilayer film mirror formed of a plurality of laminated films having different refractive indices, a transparent or semi-transparent electrode, a light emitting layer and a metal electrode in a superimposed manner. Light generated in the light emitting layer repeatedly reflects between the multilayer film mirror and the metal electrode (both of which serve as a reflector) to resonate.

In a second aspect of the organic electroluminescent element, a transparent or semi-transparent electrode and a metal electrode (both of which function as a reflector) are provided over a transparent substrate, and light generated in a light emitting layer repeatedly reflects therebetween to resonate.

To form a resonance structure, an optical path, which is determined based on effective refractive indices of two reflectors, refractive indices of different layers formed between the two reflectors and the thicknesses of these layers, is controlled so as to be an optimal value for obtaining a desired resonance wavelength.

The mathematical expression in the case of the first aspect is described, for example, in JP-A No. 9-180883.

The mathematical expression in the case of the second aspect is described, for example, in JP-A No. 2004-127795.

### —Application—

The application purpose of the organic electroluminescent element of the present invention is not particularly limited and may be suitably selected in accordance with the intended use, however, it can be suitably used in display elements, display devices, back lights, electrophotography, illumination light sources, recording light sources, exposure light sources, reading light sources, indicators, advertising sign boards, interior goods, optical communications, and the like.

As a method of making the organic electroluminescent display device full colors, for example, as described in Monthly Display, pp. 33-37 (September, 2000), there have been known a three-color light-emitting method of arranging organic EL elements emitting lights corresponding to three primary colors (blue (B), green (G) and red (R)) of colors on a substrate; a white color method of separating white color emission by an organic EL element for white color emission to three colors through a color filter; and a color-converting method of converting blue color emission by an organic EL element for blue color emission to red (R) and green (G) through a fluorescent dye layer.

### Examples

Hereinafter, the present invention will be further described in detail with reference to Examples, which, however, shall not be construed as limiting the present invention.

### Example 1

### <Production of Particle-Fixed Substrate 1>

Polystyrene particles (refractive index: 1.59) having a mono-dispersed particle size distribution, a coefficient of variation of 1.6%, an average particle diameter of 500 nm, and a trimethylammonium group on its surface was used to prepare a dispersion liquid having a particle concentration of 8% by mass. This dispersion liquid was diluted with ultrapure water to a concentration of 0.05% by mass and then subjected to a desalination treatment through dialysis. In the dispersion liquid, a glass substrate (thickness: 0.5 mm, refractive index: 1.5), which had been washed with O₃ by UV irradiation, was immersed and then left at rest at room temperature for 30 minutes. Subsequently, the substrate was rinsed and heated in boiled ultrapure water for 30 seconds, and further rinsed with room-temperature ultrapure water for 30 seconds, followed by cooling. The substrate was taken out from the ultrapure water, and extra water was removed from the substrate by compressed air, followed by drying under reduced pressure at room temperature for 3 hours, thereby a particle-fixed substrate 1 was produced.

The particle size distribution and the average particle diameter of the polystyrene particles were measured by observing a SEM image through a scanning electron microscope (SEM).

The obtained particle-fixed substrate 1 was found to have a surface coverage of 20% from the analysis of the SEM image. FIG. 5 illustrates a SEM image of the particle-fixed substrate 1. The result illustrated in FIG. 5 demonstrates that particles were arranged and fixed on the substrate.

### <Production of Particle-Fixed Substrate 2>

Polystyrene particles (refractive index: 1.59) having a mono-dispersed particle size distribution, a coefficient of variation of 1.6%, an average particle diameter of 500 nm, and a trimethylammonium group on its surface was used to prepare a dispersion liquid having a particle concentration of 8% by mass. This dispersion liquid was diluted with ultrapure water to a concentration of 0.02% by mass and then subjected to a desalination treatment through dialysis. In the dispersion liquid, a glass substrate (thickness: 0.5 mm, refractive index: 1.5), which had been washed with O₃ by UV irradiation, was immersed and then left at rest at room temperature for 30 minutes. Subsequently, the substrate was rinsed and heated in boiled ultrapure water for 30 seconds, and further rinsed with room-temperature ultrapure water for 30 seconds, followed by cooling. The substrate was taken out from the ultrapure water, and extra water was removed from the substrate by compressed air, followed by drying under reduced pressure at room temperature for 3 hours, thereby a particle-fixed substrate 2 was produced.

The obtained particle-fixed substrate 2 was found to have a surface coverage of 10% from the analysis of the SEM image.

### <Production of Particle-Fixed Substrate 3>

Polystyrene particles (refractive index: 1.59) having a mono-dispersed particle size distribution, a coefficient of variation of 1.6%, an average particle diameter of 500 nm, and a trimethylammonium group on its surface was used to prepare a dispersion liquid having a particle concentration of 8% by mass. This dispersion liquid was diluted with ultrapure water to a concentration of 0.01% by mass and then subjected to a desalination treatment through dialysis. In the dispersion liquid, a glass substrate (thickness: 0.5 mm, refractive index: 1.5), which had been washed with O₃ by UV irradiation, was immersed and then left at rest at room temperature for 30 minutes. Subsequently, the substrate was rinsed and heated in boiled ultrapure water for 30 seconds, and further rinsed with room-temperature ultrapure water for 30 seconds, followed by cooling. The substrate was taken out from the ultrapure water, and extra water was removed from the substrate by compressed air, followed by drying under reduced pressure at room temperature for 3 hours, thereby a particle-fixed substrate 3 was produced.

The obtained particle-fixed substrate 3 was found to have a surface coverage of 4% from the analysis of the SEM image.

### <Production of Particle-Fixed Substrate 4>

Polystyrene particles (refractive index: 1.59) having a mono-dispersed particle size distribution, a coefficient of variation of 1.6%, an average particle diameter of 500 nm, and a trimethylammonium group on its surface was used to prepare a dispersion liquid having a particle concentration of 8% by mass. This dispersion liquid was diluted with ultrapure water to a concentration of 0.1% by mass and then subjected to a desalination treatment through dialysis. In the dispersion liquid, a glass substrate (thickness: 0.5 mm, refractive index: 1.5), which had been washed with O₃ by UV irradiation, was immersed and then left at rest at room temperature for 30 minutes. Subsequently, the substrate was rinsed and heated in boiled ultrapure water for 30 seconds, and further rinsed with room-temperature ultrapure water for 30 seconds, followed by cooling. The substrate was taken out from the ultrapure water, and extra water was removed from the substrate by compressed air, followed by drying under reduced pressure at room temperature for 3 hours, thereby a particle-fixed substrate 4 was produced.

The obtained particle-fixed substrate 4 was found to have a surface coverage of 30% from the analysis of the SEM image.

### <Production of Particle-Fixed Substrate 5>

Polystyrene particles (refractive index: 1.59) having a mono-dispersed particle size distribution, a coefficient of variation of 1.6%, an average particle diameter of 500 nm, and a trimethylammonium group on its surface was used to prepare a dispersion liquid having a particle concentration of 8% by mass. This dispersion liquid was diluted with ultrapure water to a concentration of 0.5% by mass and then subjected to a desalination treatment through dialysis. In the dispersion liquid, a glass substrate (thickness: 0.5 mm, refractive index: 1.5), which had been washed with O₃ by UV irradiation, was immersed and then left at rest at room temperature for 30 minutes. Subsequently, the substrate was rinsed and heated in boiled ultrapure water for 30 seconds, and further rinsed with room-temperature ultrapure water for 30 seconds, followed by cooling. The substrate was taken out from the ultrapure water, and extra water was removed from the substrate by compressed air, followed by drying under reduced pressure at room temperature for 3 hours, thereby a particle-fixed substrate 5 was produced.

The obtained particle-fixed substrate 5 was found to have a surface coverage of 40% from the analysis of the SEM image.

### <Film Formation 1>

The particle-fixed substrates 1 to 5 were each used in the combination shown in Table 1 and subjected to a vacuum film formation according to the following manner. In the vacuum film formation, each of the particle-fixed substrates was subjected to vacuum vapor deposition from a perpendicular direction with respect to the surface thereof.

First, aluminum (Al) was vacuum vapor deposited, as an anode, on the particle-fixed substrate so as to have a thickness of 100 nm.

Next, 2-TNATA[4,4′,4″-tris(2-naphtylphenylamino)triphenylamine] and MnO₃ were vacuum vapor deposited at a ratio of 7:3 (by mass) on the aluminum film, so as to have a thickness of 20 nm, thereby forming a hole injection layer.

Next, on the hole injection layer, 2-TNATA doped with 1.0% by mass F4-TCNQ(2,3,5,6-tetrafluoro-7,7,8,8-tetracyanoquinodimethane) was vacuum vapor deposited so as to have a thickness of 141 nm, thereby forming a first hole transport layer.

Next, on the first hole transport layer, α-NPD [N,N′-(dinapthtylphenylamino)pyrene] was vacuum vapor deposited so as to have a thickness of 10 nm, thereby forming a second hole transport layer.

Next, on the second hole transport layer, a hole transport material A represented by the following structural formula was vacuum vapor deposited so as to have a thickness of 3 nm, thereby forming a third hole transport layer.

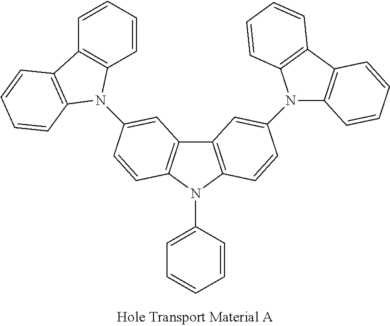

Next, on the third hole transport layer, CBP (4,4′-dicarbazole-biphenyl) serving as a host material and a light emitting material A represented by the following structural formula and serving as a light emitting material were vacuum vapor deposited at a ratio of 85:15 (by mass) so as have a thickness of 20 nm, thereby forming a light emitting layer.

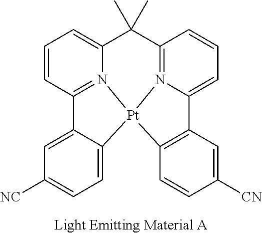

Next, on the light emitting layer, BAlq(aluminum(III)bis(2-methyl-8-quinolinato)-4-phenylphenolate) was vacuum vapor deposited so as to have a thickness of 39 nm, thereby forming a first electron transport layer.

Next, on the first electron transport layer, BCP(2,9-dimethyl-4,7-diphenyl-1,10-phenanthrolin) was vacuum vapor deposited so as to have a thickness of 1 nm, thereby forming a second electron transport layer.

Next, on the second electron transport layer, LiF was vacuum vapor deposited so as to have a thickness of 1 nm, thereby forming a first electron injection layer.

Next, on the first electron injection layer, aluminum (Al) was vacuum vapor deposited so as to have a thickness of 1 nm, thereby forming a second electron injection layer.

Next, on the second electron injection layer, silver (Ag) was vacuum vapor deposited as a cathode so as to have a thickness of 20 nm. With the above described procedure, each organic electroluminescent element was produced.

### <Film Formation 2>

The particle-fixed substrates 1 to 5 were each used in the combination shown in Table 1 and subjected to a vacuum film formation according to the following procedure. In the vacuum film formation, each of the particle-fixed substrates was subjected to vacuum vapor deposition from an oblique direction with respect to the surface thereof. Further, the vapor deposition was performed by rotating the substrate so that a thin film was formed over the back side of the particles.

Specifically, on each of the particle-fixed substrate, vacuum film formation was carried out in the same procedure as described in <Film Formation 1>, so that each of the layers formed had the same thickness as described above, whereby each organic electroluminescent element was produced.

### <Removal of Particles>

Each of the organic electroluminescent elements produced was treated in inactive gas atmosphere, and an adhesive sheet (ICROS TAPE, produced by Mitsui Chemicals, Inc.) was attached to a film-formed surface of the EL element and then pealed off therefrom to thereby remove the particles. FIG. 6 illustrates a SEM image of a substrate surface which was obtained after a thin film was formed using the particle-fixed substrate 1 and fixed particles were removed from the surface thereof. From the result illustrated in FIG. 6, it was found that the particles were removed from the substrate surface and concave portions were formed therein.

### <Evaluation>

Each of the organic electroluminescent elements produced was evaluated with the proviso that the light extraction quantity and the power supply efficiency thereof under application of an electrical current of 0.025 mA/cm² (in the case where particles are not provided on the substrate) are each graded as “1” (as a reference value). The evaluation results are shown in Table 1. Note that when the particle-fixed substrate 5 was used, the organic EL element did not emit light due to occurrence of wiring disconnection or the like, and in this case, the organic EL elements were not evaluated.

### —Light Extraction Quantity and Power Supply Efficiency—

The light extraction quantity and power supply efficiency of the organic electroluminescent elements were measured using an external quantity efficiency measuring instrument (manufactured by Hamamatsu Photonics K.K.).

TABLE 1

| | | | | Light | |
|---|---|---|---|---|---|
| | | | | extraction | |
| | Production of | | | quantity | Power |
| | particle-fixed | Film | Removal of | per unit | supply |
| No. | substrate | formation | fine particles | area | efficiency |
| 1 | Not produced | 1 | Not removed | 1 | 1 |
| 2 | 1 | 1 | Not removed | 1.1 | 1.3 |
| 3 | 1 | 1 | Removed | 1.1 | 1.4 |
| 4 | 1 | 2 | Not removed | 1.5 | 2.0 |
| 5 | 1 | 2 | Removed | 1.4 | 1.8 |
| 6 | 2 | 1 | Not removed | 1.1 | 1.2 |
| 7 | 2 | 2 | Not removed | 1.3 | 1.7 |
| 8 | 3 | 1 | Not removed | 1.0 | 1.1 |
| 9 | 3 | 2 | Not removed | 1.2 | 1.5 |
| 10 | 4 | 1 | Not removed | 1.1 | 1.4 |
| 11 | 4 | 2 | Not removed | 1.3 | 2.1 |

### Example 2

### <Film Formation 3>

The particle-fixed substrate 1 was subjected to a vacuum film formation according to the following procedure. In the vacuum film formation, the particle-fixed substrate was subjected to vacuum vapor deposition from an oblique direction with respect to the surface thereof. Further, the vapor deposition was performed by rotating the substrate so that a thin film was formed over the back side of the particles.

First, ITO was vacuum vapor deposited, as an anode, on the particle-fixed substrate so as to have a thickness of 100 nm.

Next, 2-TNATA[4,4′,4″-tris(2-naphtylphenylamino)triphenylamine] and MnO₃ were vacuum vapor deposited at a ratio of 7:3 (by mass) on the ITO film, so as to have a thickness of 20 nm, thereby forming a hole injection layer.

Next, on the hole injection layer, 2-TNATA doped with 1.0% by mass F4-TCNQ(2,3,5,6-tetrafluoro-7,7,8,8-tetracyanoquinodimethane) was vacuum vapor deposited so as to have a thickness of 141 nm, thereby forming a first hole transport layer.

Next, on the first hole transport layer, α-NPD[N,N′-(dinapthtylphenylamino)pyrene] was vacuum vapor deposited so as to have a thickness of 10 nm, thereby forming a second hole transport layer.

Next, on the second hole transport layer, a hole transport material A represented by the following structural formula was vacuum vapor deposited so as to have a thickness of 3 nm, thereby forming a third hole transport layer.

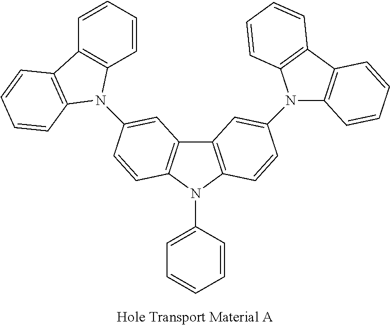

Next, on the third hole transport layer, CBP (4,4′-dicarbazole-biphenyl) serving as a host material and a light emitting material A represented by the following structural formula and serving as a light emitting material were vacuum vapor deposited at a ratio of 85:15 (by mass) so as have a thickness of 20 nm, thereby forming a light emitting layer.

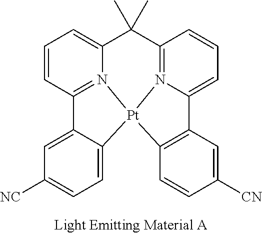

Next, on the light emitting layer, BAlq(aluminum(III)bis(2-methyl-8-quinolinato)-4-phenylphenolate) was vacuum vapor deposited so as to have a thickness of 39 nm, thereby forming a first electron transport layer.

Next, on the first electron transport layer, BCP(2,9-dimethyl-4,7-diphenyl-1,10-phenanthrolin) was vacuum vapor deposited so as to have a thickness of 1 nm, thereby forming a second electron transport layer.

Next, on the second electron transport layer, LiF was vacuum vapor deposited so as to have a thickness of 1 nm, thereby forming a first electron injection layer.

Next, on the first electron injection layer, aluminum (Al) was vacuum vapor deposited as a cathode so as to have a thickness of 100 nm.

### <Removal of Particles>

The organic electroluminescent element produced was treated in inactive gas atmosphere, and an adhesive sheet (ICROS TAPE, produced by Mitsui Chemicals, Inc.) was attached to a film-formed surface of the EL element and then pealed off therefrom to thereby remove the particles.

### <Vapor Deposition of Surface Layer>

On the organic electroluminescent element from which surface particles had been removed, SiONx was formed as an insulation layer by a DVD method, so as to have a thickness of 500 nm. Subsequently, on the insulation layer, aluminum (Al) was deposited as a reflective layer, so as to have a thickness of 100 nm. With this procedure, an organic electroluminescent element of Example 2 was produced.

### <Evaluation>

The organic electroluminescent element of Example 2 was evaluated in the same manner as in Example 1. When the light extraction quantity and the power supply efficiency under application of an electrical current of 0.025 mA/cm² (in the case where particles are not provided on the substrate) (configuration of the organic EL element in Film Formation 3) are each graded as “1” (as a reference value), the organic electroluminescent element of Example 2 was found to have a light extraction quantity of 1.5 times and a power supply efficiency of 2.1 times the reference values.

The organic electroluminescent element of the present invention has high-light extraction efficiency, causes less light bleeding and enables reduction of power consumption, and it can be suitably used in display elements, display devices, back lights, electrophotography, illumination light sources, recording light sources, exposure light sources, reading light sources, indicators, advertising sign boards, interior goods, optical communications, and the like.

What is claimed is:

1. A method for producing an organic electroluminescent element, comprising:
arranging, on a surface of a substrate having an electrostatic charge, particles provided with a surface electrostatic charge opposite to the electrostatic charge on the surface of the substrate, so that the particles are fixed on the surface of the substrate with an electrostatic force, and
forming a thin film on the surface of the substrate on which the particles have been fixed.

2. The method according to claim 1, further comprising: forming a surface layer on a surface of the thin film and surfaces of the particles.

3. The method according to claim 1, wherein the surface coverage of the particles fixed on the surface of the substrate is 0.1% to 20%.

4. The method according to claim 1, wherein when a total thickness of the thin film formed in the forming the thin film is defined as X μm, and an average particle diameter of the particles is defined as Y μm, X and Y satisfy the relationship X/Y<1.

5. The method according to claim 1, wherein the thin film is formed by a vacuum vapor deposition method.

6. An organic electroluminescent element comprising:
a substrate having an electrostatic charge on a surface thereof, and
particles provided with a surface electrostatic charge opposite to the electrostatic charge on the surface of the substrate,
wherein the organic electroluminescent element produced by a method for producing an organic electroluminescent element which comprises: arranging the particles on the surface of the substrate, so that the particles are fixed on the surface of the substrate with an electrostatic force, and forming thin films on the surface of the substrate on which the particles have been fixed.

7. The method according to claim 1, further comprising: removing the particles from the surface of the substrate on which the thin film has been formed.

8. The method according to claim 7, further comprising: forming a surface layer on surfaces of concave portions formed by removing the particles and on a surface of the thin film.

9. The method according to claim 7, wherein the surface coverage of the particles fixed on the surface of the substrate is 0.1% to 20%.

10. The method according to claim 7, wherein when a total thickness of the thin film formed in the forming the thin film is defined as X μm, and an average particle diameter of the particles is defined as Y μm, X and Y satisfy the relationship X/Y<1.

11. The method according to claim 7, wherein the thin film is formed by a vacuum vapor deposition method.

12. The method according to claim 7, wherein the particles are removed from the surface of the substrate using an adhesive tape.

13. An organic electroluminescent element comprising:
a substrate having an electrostatic charge on a surface thereof, and
particles provided with a surface electrostatic charge opposite to the electrostatic charge on the surface of the substrate,
wherein the organic electroluminescent element produced by a method for producing an organic electroluminescent element which comprises: arranging the particles on the surface of the substrate, so that the particles are fixed on the surface of the substrate with an electrostatic force, forming thin films on the surface of the substrate on which the particles have been fixed, and removing the particles from the surface of the substrate on which the thin films have been formed.
